(19) United States
(12) Patent Application Publication
(10) Pub. No.: US 2026/0141147 A1
(43) Pub. Date: May 21, 2026

(54) BOOLEAN REASONING GUIDED UNGROUPING ACROSS CIRCUIT DESIGN HIERARCHY

(71) Applicant: Synopsys, Inc., Sunnyvale, CA (US)

(72) Inventors: Eleonora TESTA, Sunnyvale, CA (US); Alan Allwyn VAZ, Sunnyvale, CA (US); Abhishek KUMAR, Karantaka (IN); Brian E. LOCKYEAR, Portland, OR (US); Luca Gaetano AMARU, Santa Clara, CA (US); Elena TEICA, Santa Clara, CA (US); Giulia MEULI, Roma (IT); Vishal F. ARALIKATTI, Karantaka (IN)

(21) Appl. No.: 19/181,093

(22) Filed: Apr. 16, 2025

(30) Foreign Application Priority Data
Nov. 18, 2024 (IN) 202441089204

(51) Int. Cl. G06F 30/3323

(52) U.S. Cl. CPC G06F 30/3323

(57) ABSTRACT

A system and method for synthesizing and verifying a circuit design includes receiving a circuit design. An equivalency metric is determined across a first hierarchy and a second hierarchy from hierarchies of the circuit design. The equivalency metric is based on one or more of a combinational element equivalency and a sequential element equivalency across the first hierarchy and the second hierarchy. An updated circuit design is generated by ungrouping the first hierarchy of the hierarchies into the second hierarchy of the hierarchies based on the equivalency metric.

### RELATED APPLICATION

This application claims the benefit of Indian provisional patent application serial number 202441089204, filed Nov. 18, 2024, which is hereby incorporated herein by reference.

### TECHNICAL FIELD

The present disclosure generally relates to an electronic design automation (EDA) system, and, in particular, to ungrouping hierarchies of a circuit design using a guided ungrouping process.

### BACKGROUND

Integrated circuit (IC) devices are designed via a design process. The design process for an IC device includes designing a circuit design, and testing and validating the circuit design of an IC device. The circuit design is synthesized to perform the testing process and the validation process. To synthesize a circuit design, the circuit behavioral description (e.g., at a register transfer level (RTL)) is transformed into a design implementation (e.g., a netlist) in terms of logic gates. A tested and validated circuit design is output and used to manufacture the final IC device

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates a flowchart of a method for ungrouping hierarchies and generating an updated circuit design in accordance with some embodiments of the present disclosure.

FIG. 2 illustrates a directed tree graph for hierarchies of a circuit design in accordance with some embodiments of the present disclosure.

FIG. 3 illustrates a circuit design in accordance with some embodiments of the present disclosure.

FIG. 4 illustrates a circuit design having reduced hierarchies in accordance with some embodiments of the present disclosure.

FIG. 5 illustrates a circuit design in accordance with some embodiments of the present disclosure.

FIG. 6 illustrates another directed tree graph for hierarchies of a circuit design in accordance with some embodiments of the present disclosure.

FIG. 7 illustrates another circuit design in accordance with some embodiments of the present disclosure.

FIG. 8 illustrates a global network for hierarchies of a circuit design in accordance with some embodiments of the present disclosure.

FIG. 9 illustrates another circuit design having reduced hierarchies in accordance with some embodiments of the present disclosure.

FIG. 10 illustrates registers having different states in accordance with some embodiments of the present disclosure.

FIG. 11 depicts a flowchart of various processes used during the design and manufacture of an integrated circuit in accordance with some embodiments of the present disclosure.

FIG. 12 depicts a diagram of an example computer system in which embodiments of the present disclosure may operate.

### DETAILED DESCRIPTION

Aspects of the present disclosure relate to Boolean reasoning guided ungrouping across circuit design hierarchies.

During the design process of an integrated circuit (IC) device, the corresponding circuit design is tested and validated. The tested and validated circuit design is used to manufacture the final IC device. The testing and validation process includes synthesizing the circuit design. Synthesizing the circuit design includes transforming a circuit behavioral description (e.g., at a register transfer level (RTL)) into a design implementation (e.g., a netlist) in terms of logic gates. The synthesizing process includes an ungrouping process. Ungrouping is applied to the hierarchies of a circuit design. The circuit design includes multiple hierarchies or hierarchical levels (also referred to herein as hierarchies), where each hierarchical level includes a portion of the circuit design that represents a particular functionality within the circuit design. During the ungrouping process, hierarchies of a circuit design are dissolved (e.g., removed). Dissolving hierarchies includes dissolving the boundaries between hierarchies. The hierarchy dissolving process is a boundary optimization process. Dissolving, or removing, the hierarchical boundaries, unlocks more optimization opportunities and improve the Quality of Results (QoR) (e.g., power, performance, and area (PPA)) of the corresponding manufactured IC chip.

Many boundary optimization processes are widely used within circuit design process flows. In a circuit design process flow, logic optimization processes are applied to the circuit logic elements within the circuit design. However, many logic optimization processes are unable to be completed without performing ungrouping. A boundary optimization process may be used to overcome the restrictions posed by hierarchical boundaries by identifying optimization opportunities within the logic elements of a circuit design. A boundary optimization process leverages a global visibility of the overall logic of a circuit design. During a boundary optimization process, the changes that can be made are limited to changes that are not disruptive to the boundaries themselves (e.g., constant propagation). Performing more aggressive logic restructuring can compromise the boundaries, requiring port-punching and increasing the verification of a circuit design.

Determining the boundaries for the ungrouping process is a complex problem that is based on understanding how ungrouping impacts all the steps involved in the circuit design synthesis flow. A circuit design synthesis flow integrates and intertwines different processes and heuristics with varying scalability properties. For example, a more aggressive ungrouping process, which may generate a more flattened circuit design netlist, may lead to QOR loss. In various instances, some of the hierarchical boundaries are to be preserved as the boundaries are the natural cut points for the optimization engines to provide stronger logic simplifications. In an example where the ungrouping process fails to select the best boundaries to be dissolved or kept, partitioning can be used to set boundaries in a flat design, but recovering the same strong boundaries is difficult, and flat circuit designs may lead to issues that arise during formal verification of the circuit design.

An ungrouping process uses specific processes (strategies) to determine which hierarchies of a circuit design to ungroup (e.g., dissolve or remove). Current ungrouping processes are based on hierarchy sizes and prevent large parent hierarchies. However, such processes are unable to identify all of the possible hierarchies that can be ungroup. Accordingly, the ungrouping process as described herein is guided based on cost metrics and includes different ungrouping processes at different flow steps to identify the boundaries that can be dissolved (ungrouped).

Technical advantages of the present disclosure include, but are not limited to a guided ungrouping process that uses cost metrics to determine how to perform the ungrouping process (e.g., to identify which hierarchical boundaries to dissolve). The guided ungrouping process can be integrated into different circuit design steps within the circuit design process. The guided ungrouping process extracts data that is used to perform ungrouping. The data may be described as cost metrics. In one or more examples, the cost metrics include one or more of logic equivalences, XOR-intensiveness, and logic connectivity. The cost metrics are extracted during the guided ungrouping process. The described guided ungrouping process may be fully integrated within a circuit design process and exploits costs metrics to determine which hierarchy boundaries to ungroup to minimize area. In various examples, the guided ungrouping process described herein reduces the amount of computer system runtime and processor resources during the circuit design process. For example, a circuit design may be optimized without compromising the hierarchical boundaries of the circuit design ensuring that the design flow associated with the circuit design is not disrupted. Additionally, the wire-length within the manufactured IC device is decreased. Further, the PPA of the manufactured IC device is increased. Accordingly, the manufacturing cost of an IC device is increased and the performance the manufactured IC device is improved.

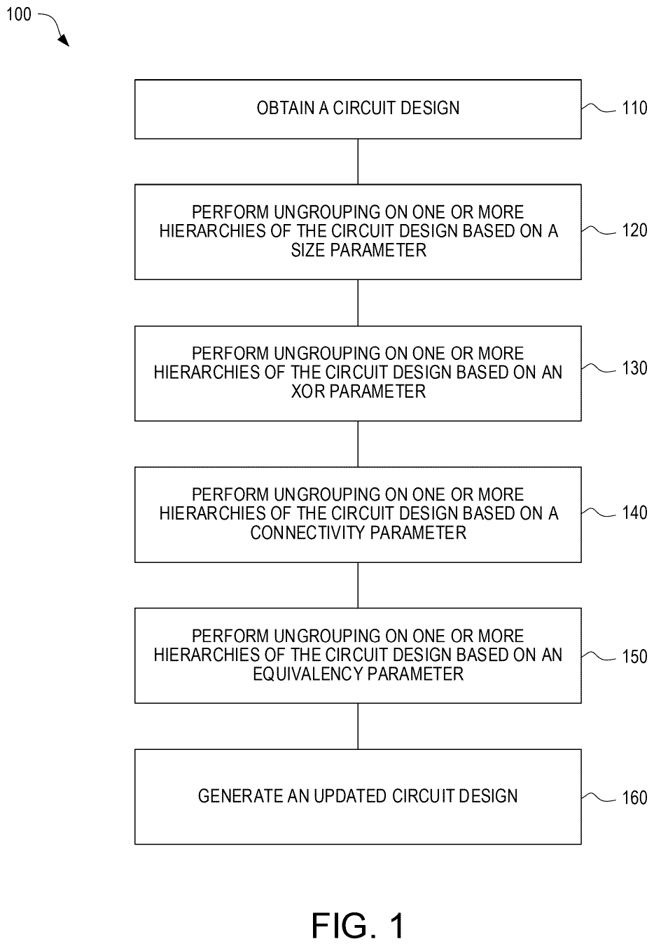

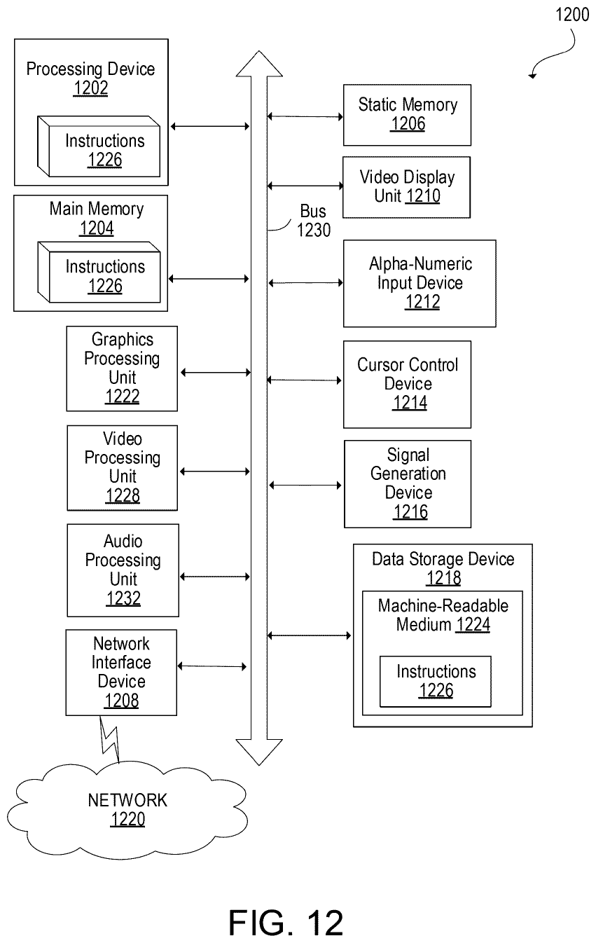

FIG. 1 illustrates a flowchart of a method 100 for ungrouping hierarchies within a circuit design for an IC device. In one example, the method 100 is performed by a computer system (e.g., the computer system 1200 of FIG. 12). In one or more examples, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to perform the method 100 of FIG. 1.

At 110, a circuit design is obtained. For example, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to obtain (e.g., receive) the circuit design from the memory device. In one example, the circuit design is a register-transfer level (RTL) file. In another examples, the circuit design may be represented by other file types.

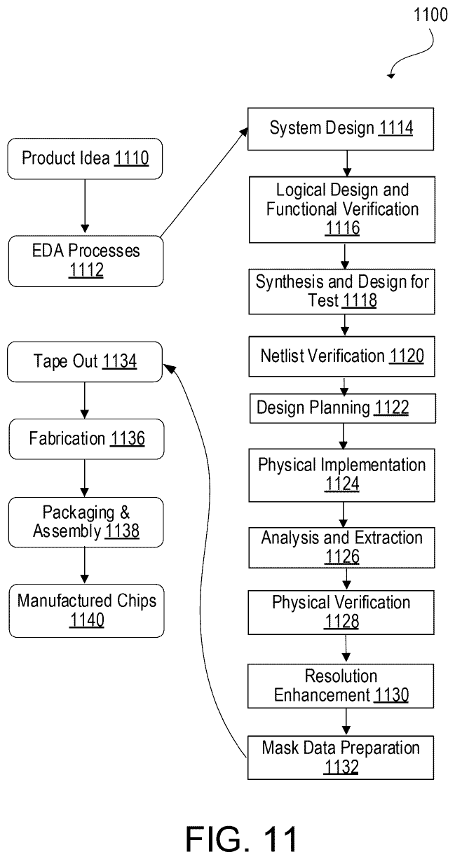

At 120, ungrouping is performed on one or more hierarchies of the circuit design based on a size parameter. In one or more examples, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to perform ungrouping of one or more hierarchies of the circuit design on a size parameter. Ungrouping is a step performed during logic synthesis of a circuit design (e.g., see 1116 of FIG. 11). Ungrouping allows for optimization of the circuit logic elements across hierarchical boundaries to create an optimized circuit design. In one example, a hierarchy H is a collection of instances (e.g., logic elements) representing different modules within a circuit design. For a given hierarchy H, the corresponding parent hierarchy is the hierarchy that instantiates and contains H. Further, children hierarchies of H are instantiated and contained by H. In one or more examples, ungrouping of hierarchy H includes ungrouping hierarchy H into the corresponding parent hierarchy. The boundaries of hierarchy H are dissolved and the logic of hierarchy H is collapsed into the corresponding hierarchy H.

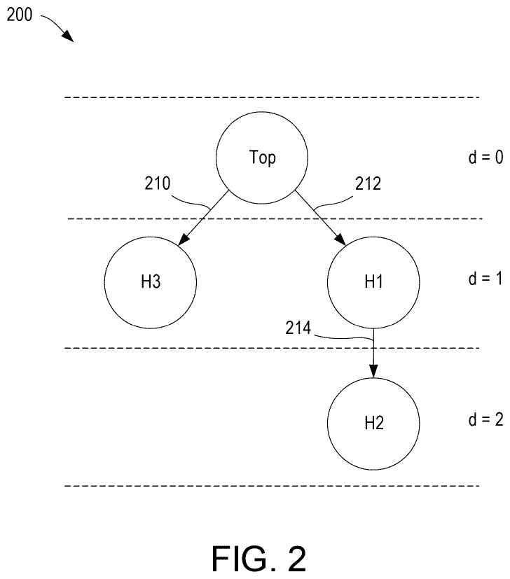

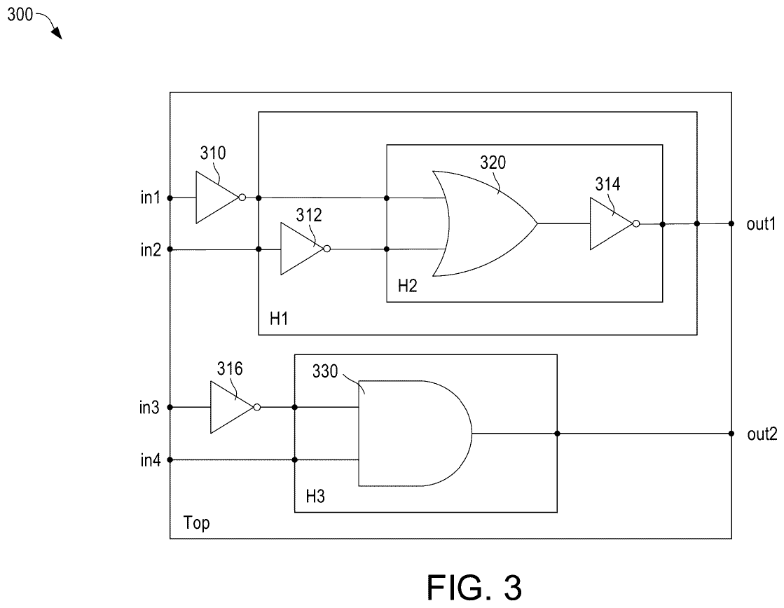

In one or more examples, the hierarchical structure of a circuit design is modeled as a directed tree graph. FIG. 2 illustrates a directed tree graph 200 including hierarchies represented by vertex Top, vertex H1, vertex H2, and vertex H3. The directed tree graph 200 corresponds to the circuit design 300 of FIG. 3. The circuit design 300 includes hierarchies Top, H1, H2, and H3. Each of the hierarchies Top, H1, H2, and H3 corresponds to a respective one of the vertices Top, H1, H2, and H3. The directed tree graph 200 models the hierarchical structure of the circuit design 300. The edges 210, 212, and 214 of the tree graph 200 connect corresponding vertices and represent the parent/child relationships of the corresponding hierarchies. Each vertex H1, H2, and H3 has a distance d defined by the number of edges from the vertex Top. For example, the distance associated with the vertex H1 is d=1 as the vertex H1 is separated from the vertex Top by one edge, edge 212. Each edge refers to a hierarchical level. The distance associated with the vertex H2 is d=2 as the vertex H2 is separated from the vertex Top by two edges, edge 212 and edge 214. The distance associated with the vertex H3 is d=1 as the vertex H3 is separated from the vertex Top by one edge, edge 210.

Referring to FIG. 3, the hierarchy Top includes the logic elements external to (e.g., inverters 310 and 316) the hierarchies H1, H2, and H3 and the logic elements within the hierarchies H1, H2, and H3. The hierarchy H2 is a child hierarchy of hierarchy H1. The hierarchy H1 includes inverter 312 that is external to the hierarchy H2, and the logic elements within the hierarchy H2. The hierarchy H2 includes OR gate 320 and inverter 314. The hierarchy H 3 includes AND gate 330. The hierarchies Top, H1, H2, and H3 in the circuit design 300 are represented by a corresponding vertex in the tree graph 200.

In one or more examples, the processing device determines the size (e.g., size parameter) of the hierarchies (e.g., hierarchical blocks). The size of the hierarchical blocks corresponds to a cell count of the hierarchical blocks. With reference to FIG. 3, the processing device determines the size for the hierarchies Top, H1, H2, and H3 of the circuit design 300. In one example, the size (or cell count) is an NAND2 gate count. The size of each hierarchy is compared to a threshold size value to determine if a hierarchy is to be ungrouped. Based on the size of a hierarchy being less than to the threshold size value, the hierarchy is ungrouped. In one example, a hierarchy is ungrouped based on the corresponding size being less than or equal to the threshold size value. The threshold size value is selected to prevent the creation of large parent hierarchies and/or a completely flattened (e.g., fully ungrouped) circuit design. In one example, the size of a hierarchy corresponds to the number of NAND2 equivalent gates within the hierarchy. Further, the threshold size value corresponds to X number of NAND equivalent gates. X may be set to 100, 1,000, 10,000, or more. In other example, X is 15,000 or more. In one or more examples, hierarchies determined to have less than or equal to the threshold size value are ungrouped. In one or more examples, a combined size of a hierarchy and the corresponding parent hierarchy is determined and compared to the threshold size value. Based on the combined size of the hierarchies being less than (or equal to) the threshold size value, the child hierarchy is ungrouped with the parent hierarchy.

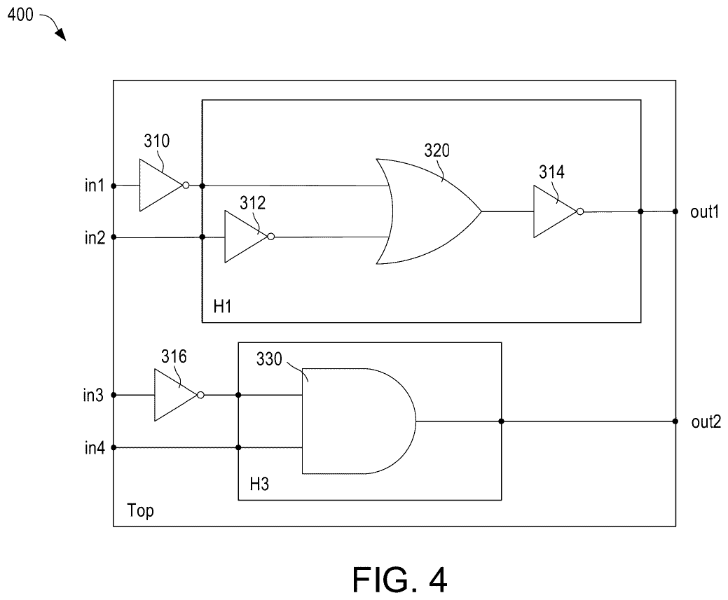

FIG. 4 illustrates the circuit design 400 where the hierarchy H2 of FIG. 3 has been ungrouped to merge into hierarchy H1. In one example, the size of hierarchy H2 is determined by a processing device and compared to the threshold size value. Based on the size of hierarchy H2 being determined to be less than the threshold size value, the processing device dissolves the boundary between the hierarchies H1 and H2, ungrouping the hierarchy H2 into the hierarchy H1. As is illustrated in FIG. 4, the inverters 312 and 314, and the OR gate 320 are included in the hierarchy H1 as the hierarchy H2 has been dissolved into the hierarchy H1.

With further reference to FIG. 1, at 130, ungrouping is performed on one or more hierarchies of the circuit design based on an XOR parameter. In one example, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to perform ungrouping on one or more hierarchies of the circuit design based on an XOR parameter.

An XOR parameter corresponds to an XOR-intensiveness of a hierarchy, or XOR-intensive hierarchies. A circuit design with relatively XOR-intensive hierarchies creates Boolean optimization and verification challenges, therefore it is desirable to reduce such XOR-intensive hierarchies. In one example, the XOR parameter corresponds to a number of XOR gates within a hierarchy. For example, the XOR parameter is represented as a percentage of XOR gates over a total number of gates within a hierarchy and/or an absolute count of the XOR gates within a hierarchy. In one example, the processing device determines the XOR parameter for each hierarchy within a circuit design by counting the number of XOR gates and/or XOR equivalent gates (e.g., gates that may be combined to provide the functionality of an XOR gate) within the hierarchy. The number of XOR gates and/or XOR equivalent gates is compared to a total number of gates within the hierarchy to determine a corresponding XOR gate percentage (e.g., an XOR-intensiveness).

In one example, the XOR parameter for a hierarchy is compared to a threshold XOR value to determine if a hierarchy is to be dissolved (e.g., ungrouped) into the corresponding parent hierarchy. Based on the value of the XOR parameter for a hierarchy being less than and/or equal to the threshold XOR value, the hierarchy is dissolved into the corresponding parent hierarchy. In one or more examples, the XOR parameter for the parent hierarchy is additionally used to determine if a hierarchy is to be dissolved into the parent hierarchy. The XOR parameters for the child and parent hierarchies are combined (e.g., into a combined XOR parameter) and compared to the threshold XOR value to determine if the child hierarchy is to be dissolved into the parent hierarchy. Based on the combined XOR parameter being less than and/or equal to the threshold XOR value, the child hierarchy is dissolved into the parent hierarchy, ungrouping the child and parent hierarchies.

In one or more examples, the threshold XOR value corresponds to a percentage. The percentage may be 90 percent. In other examples, the percentage is less than or greater than 90 percent. In one or more examples, the threshold XOR value corresponds to an absolute count value. The absolute count value may be 500. In other examples, the absolute count value is less than or greater than 500. In other examples, the threshold XOR values include both a percentage and an absolute count value.

In one or more examples, the hierarchies that are ungrouped at 130 of the method 100 and based on the XOR parameter are hierarchies that are not ungrouped at 120 of the method 100. For example, first hierarchies of a circuit design are ungrouped based on a size parameter at 120 of the method 100 and second hierarchies of the circuit design are ungrouped based on the XOR parameter at 130 of the method 100. The first hierarchies are excluded from the hierarchies that are evaluated to be ungrouped at 130 of the method 100. In one or more examples, ungrouping based on XOR-intensiveness improves PPA of the corresponding circuit design, and decreasing the complexity of the verification process of the circuit design process.

At 140 of FIG. 1, ungrouping is performed on one or more hierarchies of the circuit design based on a connectivity parameter. In one example, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to perform ungrouping on one or more hierarchies of the circuit design based on a connectivity parameter.

In one or more examples, using the connectivity parameter during ungrouping improves connectivity and datapath extraction. Datapath extraction is an optimization technique that clusters arithmetic operators (e.g., adders, subtractors, multipliers, shifter, and/or selectors, among others). Performing ungrouping based on a connectivity parameter includes determining the arithmetic operators that are directly connected across hierarchical boundaries. The hierarchies that include the arithmetic operators that are directly connected across hierarchical boundaries are selected for ungrouping (e.g., to be dissolved). In one or more examples, a hierarchy having a larger number of arithmetic operators across a boundary has a higher chance of being ungrouped as compared to a hierarchy having a smaller number of arithmetic operators across a boundary.

In one or more examples, the processing device iterates over all boundary pins for a hierarchy, and determines the corresponding drivers and loads. In one example, determining the connectivity parameter for a hierarchy includes detecting synthetic operators that can be extracted as part of datapath blocks. Detecting an operator is based on the connectivity of the operator and the extractability of the operator. In one or more examples, extracting a cluster of operators into a datapath may not always be possible, either for functional correctness considerations (e.g., operands'truncation between operations) and/or for PPA. The datapath blocks are efficient for delay as long as internal operands are represented in carry-save format, and extraction may be limited based on such configurations.

In one example, determining the connectivity parameter includes, for each input pin of a hierarchy, determine the corresponding driver and load(s). For each load, the highest parent hierarchy is compared to the highest parent hierarchy of a corresponding driver. In one or more examples, if the highest parent hierarchy is equal to the highest parent hierarchy of a corresponding driver, then the connectivity of the corresponding operator is determined.

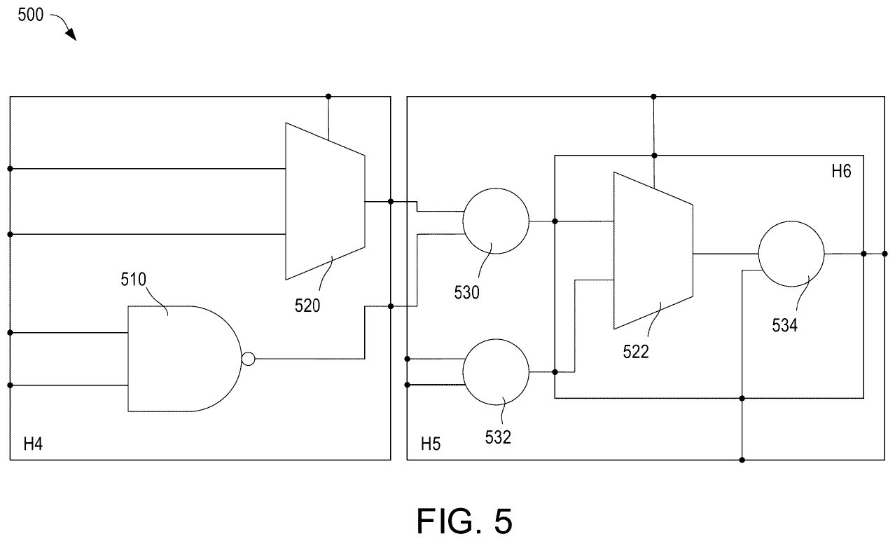

FIG. 5 illustrates the circuit design 500. The circuit design 500 includes hierarchies H4, H5, and H6. The hierarchy H6 is the child hierarchy of hierarchy H5. In one or more examples, the processing device determines a connectivity parameter based on the connections between the logic elements within the circuit design. For example, with reference to the circuit design 500 of FIG. 5, the processing device determines that the selector 520 is directly connected to the adder 530. The output of the selector 520 is directly connected to an input of the adder 530. In one example, a direct connection is a connection between two logic elements without any other elements placed (e.g., connected) in between. Further, the NAND gate 510 is directly connected to the adder 530. For example, the output of the NAND gate 510 is connected to an input of the adder 530. The adder 530 is directly connected to the selector 522. In one or more examples, the output of the adder 530 is connected to an input of the selector 522. The adder 532 is directly connected to the selector 522. The output of the adder 532 is connected to an input of the selector 522. The selector 522 is directly connected to the adder 534.

While the selector 520 is connected to the adder 530, extracting the selector 520 as part of the datapath block along with the other connected operators is not beneficial as the hierarchy H4 and the hierarchy H5 are unrelated and the hierarchy includes inputs external the hierarchy H4. Further, as the selector 522 receives input operands in a carry-save format and propagates the input operands in the same format. Extracting the selector 522 is beneficial as the inputs of the hierarchy H6 are part of the hierarchy H5, and the hierarchy H6 is dissolved (ungrouped) into the hierarchy H5, and the hierarchies H4 and H5 are not dissolved (e.g., not ungrouped). In one example, by dissolving the hierarchy H6, the selector 522, the adder 530, the adder 532, and the adder 534 may be extracted into a single datapath block. Dissolving the hierarchy H6, provides a bit-level optimization by allowing the selector 522 and the adder 534 to be represented by a carry-save format within the datapath block.

In one or more examples, the hierarchies that are ungrouped at 140 of the method 100 and based on the connectivity parameter are hierarchies that are not ungrouped at 120 or 130 of the method 100. For example, first hierarchies of a circuit design are ungrouped based on a size parameter at 120 of the method 100, second hierarchies of the circuit design are ungrouped based on the XOR parameter at 130 of the method 100, and third hierarchies of the circuit design are ungrouped based on the connectivity parameter at 140 of the method 100.

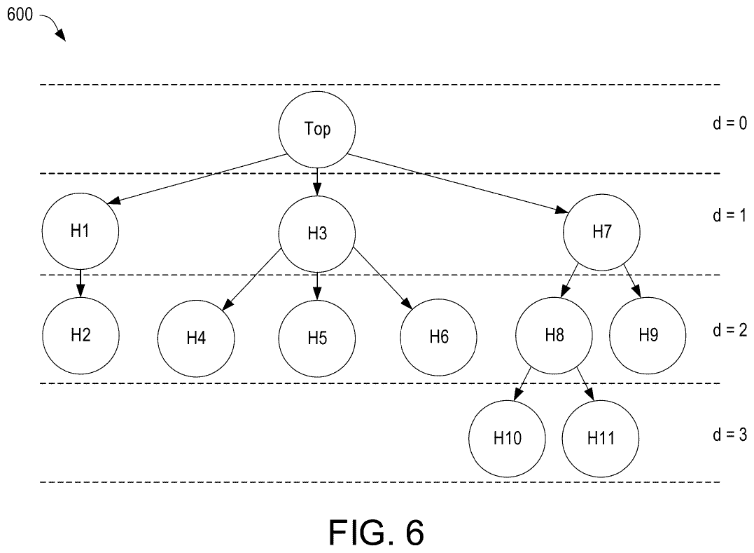

At 150 of FIG. 1, ungrouping is performed on one or more hierarchies of the circuit design based on an equivalency metric. In one example, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to perform ungrouping on one or more hierarchies of the circuit design based on an equivalency metric. The equivalency metric is determined from a graph representation of the hierarchies of the circuit design. For example, as is described in further detail in the following the equivalency metric is determined based on the directed tree graph 600 of FIG. 6. In one or more examples, the equivalency metric corresponds to gate equivalency and/or register equivalency.

In one example to perform ungrouping based on an equivalency metric, information about equivalent combinational elements (e.g., logic gates) and equivalent sequential elements (e.g., registers) across the hierarchical boundaries is determined. The information is the equivalency metric. The equivalency metric is used to guide the ungrouping process. In one or examples, the elements (e.g., gates) of the two hierarchies can be merged if the hierarchical boundaries between the hierarchies can be dissolved. Further, hierarchies that have logic overlap are ungrouped. In one or more examples, hierarchies that have equivalent logic are hierarchies that have logic overlap. In one or more examples, logic overlap between hierarchies means that the hierarchies have equivalent registers that can be merged. To merge the elements of the hierarchies, the hierarchies are ungrouped and then merged.

In one or more examples, performing ungrouping based on an equivalency metric includes determining gate equivalences and/or register equivalences for the hierarchies. Determining gate equivalences and/or register equivalences includes determining equivalence classes relative to equivalent gates and registers. The gate equivalences and register equivalences correspond to different classes. In one example, a class is characterized by an LCA hierarchy and a list of hierarchies between two hierarchical levels with equivalent elements to be ungrouped.

In one example, given two hierarchies Hx and Hy, a hierarchy is a least common ancestor (LCA) if every path from the hierarchy Hx and hierarchy Hy to the outermost hierarchy or root level of the graph passes through the LCA and if the LCA is the hierarchy with the highest distance from the outermost hierarchy having every path from Hx and Hy pass through. With reference to the directed tree graph 200 and the circuit design 300, the LCA of hierarchy H1 (vertex H1) and hierarchy H2 (vertex H2), is the hierarchy H1 (vertex H1). Further, for hierarchies H1 and H3 (vertices H1 and H3 respectively), the LCA is the hierarchy Top (vertex Top). For the hierarchies H2 and H3 (vertices H2 and H3 respectively), the LCA is the hierarchy Top (vertex Top).

When a new equivalence is added to a class, the LCA is updated and the hierarchies between the equivalent elements and the LCA are added to the list. The list of hierarchies is ungrouped. Ungrouping the hierarchies brings all equivalent gates/registers in the same class based on the corresponding selection criteria. The selection criteria may be used to keep the size of the LCA under control. In one example, the criteria include the LCA and the hierarchy to be ungrouped. In one or more examples, hierarchies determined to be ungrouped may be compared to the criteria multiple times to determine whether or not the identified hierarchies are to be ungrouped. The criteria may include the size of a hierarchy. The size of a hierarchy may correspond to the number of logic elements within the hierarchy. Hierarchies that are determined to have a number of logic elements greater than a threshold number of logic elements are not ungrouped. In one example, a hierarchy size refers to the size of the final ungrouped hierarchy. In such an example, a size (e.g., number of logic elements) of the final ungrouped hierarchy from ungrouping two or more hierarchies is determined and compared to a corresponding threshold. If the size of the final ungrouped hierarchy exceeds the corresponding threshold, the two or more hierarchies are not ungrouped.

FIG. 6 illustrates the directed tree graph 600. In the directed tree graph 600, hierarchies H1 and H10 have cross-boundary equivalences (e.g., gate equivalences and/or register equivalences). The hierarchy H1 is a child hierarchy of the hierarchy Top, and the hierarchy H10 is a child hierarchy of H8, H7, and Top. Accordingly, for hierarchy H1 and hierarchy H10, the LCA is the hierarchy Top. Further, all of the hierarchical boundaries up to the LCA is Top (lca={Top}) can be dissolved. A hierarchical list include the hierarchies H1 and H10, and the hierarchies between the hierarchies H1 and H10 and the LCA is generated (e.g., hier_list={H1, H7, H8, H10}). The hierarchies within the list are ungrouped. In one example, the hierarchies of the hierarchical list hier_list are ungrouped (e.g., the hierarchies H1, H7, H8, and H10 are ungrouped).

As is described in greater detail in the following, ungrouping is based on gate-merging information and/or register-merging information. Further, the ungrouping process can be applied to mapped gates and complex registers. A mapped gate is associated with a library cell implementation. A complex register is a register that is associated with a functionality that is more than the functionality of a simple flip-flop register. In one or more examples, a complex register has multiple next-state pins as compared to a register that has a single pin. In one example, equivalent registers include driving logic that is part of the same hierarchy. Such a relationship allows for additional optimization. Determining equivalencies includes decomposing the hierarchies of a circuit design into an And-Inverter Graph (AIG). An AIG is a logic network where the nodes perform 2-input AND gate edges can be inverted. In one or more examples, an AIG is a multi-level logic network that is used as a function representation. The AIG may be an internal network that is generated by modelling the corresponding design elements. The internal network is used to populate the equivalence matrices. In one or more examples, equivalences on the mapped network (e.g., the AIG) are determined to allow for the corresponding information to better correlate to the equivalences that are available without decomposition and technology remapping being required.

In one example, gate equivalences are determined by determining the combinational logic redundancies globally across the circuit design. As is described in greater detail in the following, such a process can be performed efficiently, is able to run on large flat networks, and finds optimization opportunities to extract information to guide ungrouping. In one example, Boolean satisfiability (SAT)-based sweeping (also referred to as SAT sweeping herein) is used to determine information about equivalencies. SAT sweeping is a process for simplifying logic network that includes merging equivalent graph vertices. In one example, SAT sweeping finds combinational equivalences in logic network exploiting partial simulation and SAT. In one or more examples, partial simulation of a network includes simulating the network using a subset of the possible input combinations. The partial simulation may be used to guide the process of disproving one or more equivalences. Random simulation is applied to the partial simulation to disprove equivalence. If a differentiating test vector is found from performing the partial simulation, the registers (or gates) are unequal. In one example, a differentiating test vector is a combination of the inputs that causes the output of a gate to be different from an assumed value. In one or more examples, partial simulation applies different input combinations to a network (i.e., test vectors) and records the output for each gate. In an example where the same test vector causes two gates to have a different output, the test vector is a differentiating test vector that demonstrates that the two gates are different (i.e., implement a different Boolean function of the inputs). If no differentiating test vector is found, then the registers (or gates) remain equal. SAT validation is used to confirm registers that are determined to be equal. In other examples, other types of processes may be used to determine the information for equivalencies.

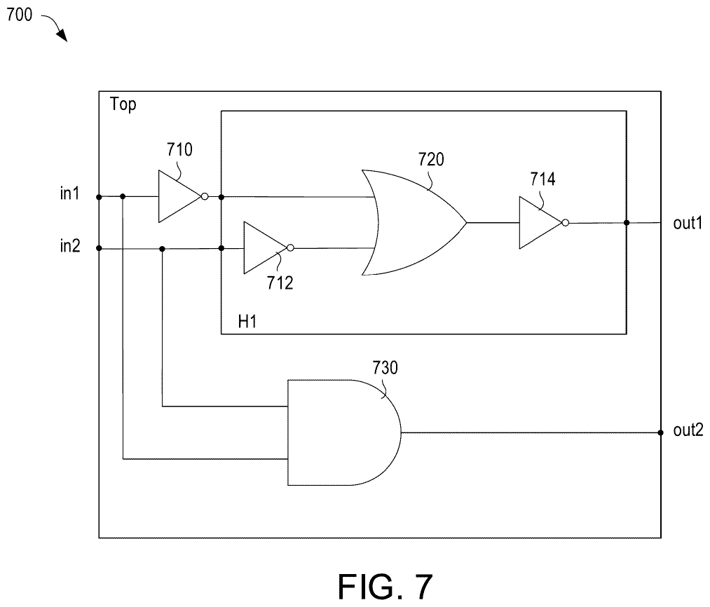

In one example to determine the gate equivalences, the global logical network across the hierarchical boundaries is determined. A global logical network is determined by collecting modelling all gates in all hierarchies within a logic network. In one or more examples, the global logical network refers to a flat AIG network generated from the circuit design with hierarchies. A global logical network is a flat network without any hierarchies. The global network includes the combinational logic of the circuit design. SAT sweeping is applied to determine the equivalence classes. In one example, the gates are all first assumed to be constant. Partial simulation is used to initialize the equivalent classes. SAT sweeping in applied to prove equivalences, to find counterexamples, and to refine classes. FIG. 7 illustrates the circuit design 700 including hierarchies Top and H1. The hierarchy H1 is a child hierarchy of the hierarchy Top. The hierarchy Top includes inverter 710 and AND gate 730. The hierarchy H1 includes inverters 712 and 714 and OR gate 720.

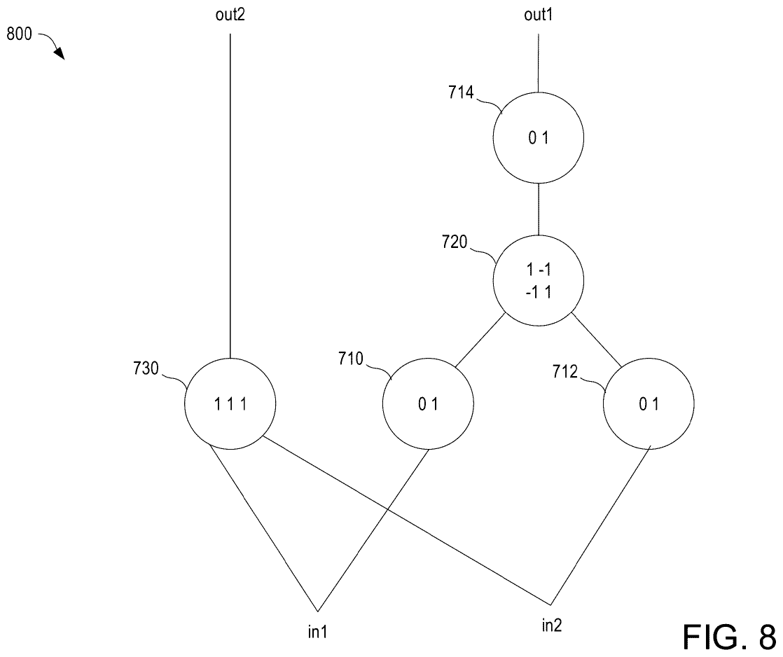

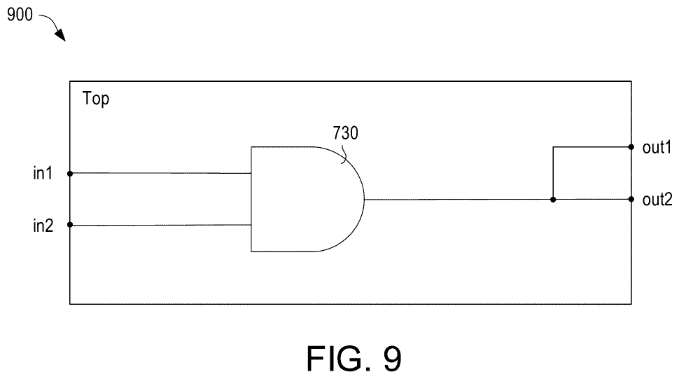

The AND gate 730 performs a two input AND operation and the OR gate 720 performs a two input OR operation. The global network is extracted across the hierarchical boundaries and is shown by the global network 800 of FIG. 8. The global network 800 is as cross-hierarchy Boolean network. In one or more examples, the global network 800 is used in SAT sweeping to determine equivalence. The numbers of the nodes 710, 712, 714, 720, and 730 of the global network 800 represent the Boolean function of each node in a textual form that describes the logic-level of the corresponding circuit elements. In other examples, other representations may be used. In one or more examples, each node within the global network 800 corresponds to a respective Boolean function in FIG. 7. In one example, the output signals out1 and out2 are determined to be equivalent by SAT sweeping and that the OR gate 720 is equivalent to the AND gate 730 up to the completion (e.g., the corresponding output out2) based on the Boolean functions of the global network 800. Accordingly, the OR gate 720 and the AND gate 730 are merged and the hierarchy H1 of the circuit design 700 is dissolved (ungrouped). FIG. 9 illustrates the circuit design 900, where the OR gate 720 and the AND gate 730 of the circuit design 700 are merged into the AND gate 730 and the corresponding hierarchies are dissolved.

In one or more examples, performing ungrouping on one or more hierarchies of the circuit design based on an equivalency metric includes determining a register equivalence and performing ungrouping based on the register equivalence. Register equivalence corresponds to equivalent and/or constant registers. In one or more examples, a circuit design is flattened, and the constant registers, equivalent registers, and/or opposite registers and ports are determined from the flattened circuit design. In one or more examples, the AIG graph is used to determine the register equivalencies by decomposing mapped gates.

In one example, determining register equivalence includes determining constant registers, determining equal registers, and determining constant ports. In one or more examples, determining register equivalences includes performing an assume and disprove technique. The process for determining register equivalence includes determining the constant registers by finding registers having clock pins that are directly tied to a signal having a constant value, a register having an asynchronous reset/set pin directly tied to a signal having a constant value of 1 (a signal that is always active), registers having synchronous reset/set pins tied to a signal having a constant value of 0 (a signal that is always active), or registers having an input (e.g., next state) directly tied to a signal having a constant value.

In one example, the constant register determination process includes determining classes of constant registers by assuming all registers as constants, and disproving the registers iteratively. The constant register determination process includes, for a given global logic represented as an AIG graph, the register synchronous input signals are determined. Further, constant values for the register outputs are assumed based on the corresponding pins. If one register has an asynchronous signal or synchronous signal, the asynchronous or synchronous signal is set to a constant 1. If a register has an asynchronous signal or synchronous signal clear signal, the asynchronous signal or synchronous signal is set to a constant value of 0. Non-resettable registers are set to a constant value of 0. The AIG graph is updated based on the constant value information, and a simulation is performed to determine and remove (e.g., filter out) the non-constant registers from the registers within the circuit design and to determine the constant registers. In one example, SAT proof is applied to the registers during the simulation to determine the constant registers. The SAT proof refers to the usage of CSAT (Circuit Based Boolean Satisfiability), which is circuit automatic test pattern generation (ATPG) with conflict-based learning to deterministically test “stuck at 0 ” or “stuck at 1” faults. The list of constant registers is added to a list of constant registers and stored within a memory device. In one example, the above steps are repeated by setting the non-resettable registers to a constant value of 1, and the determined constant registers are added to the list and stored within the memory device.

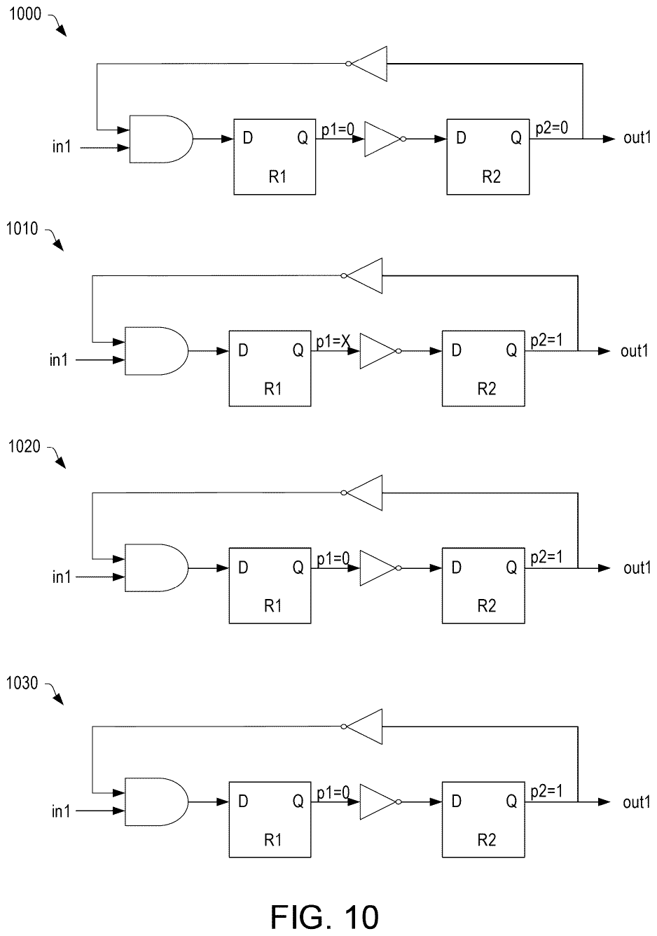

In one example with reference to FIG. 10, to determine that register R1 is constant 0 and register R2 is constant 1, the iterations 1000, 1010, 1020, and 1030 are performed. In the iteration 1000, as the registers R1 and R2 are resettable, the output p1 of register R1 is set to 0, and the output p2 of register R2 is set to 0 to disprove that R1 is not constant and R2 is a constant 1. In the iteration 1010, the output p1 of register R1 is set to X, and the output p2 of register R2 is set to 1 to disprove that R1 is a constant 0 and R2 is a constant 1. In the iteration 1020, the output p1 of register R1 is set to 0, and the output p2 of register R2 is set to 1 to disprove that R1 is a constant 0 and R2 is a constant 1. In the iteration 1030, the output p1 of register R1 is set to 0, and the output p2 of register R2 is set to 1 to disprove that R1 is a constant 0 and R2 is a constant 1. In one or more examples to perform the assume/disapprove method, all non-resettable registers are assumed to be constant zero. Partial or random simulation is applied to filter out non-constant registers. SAT proof is applied to the remaining registers, and non-constant registers are filtered out. If no new constant registers are found, then the result is final. If new constant registers are found, the entire process is repeated by assuming non-resettable registers as constant one.

Constant port detection is performed similarly as described above with regard to constant register detection. However, instead of setting the asynchronous signal or synchronous signal to a constant value, the ports are set to a constant value of 1 or 0. The detected list of constant ports is stored within the memory device.

In one or more examples, equivalent register detection is performed to determine equivalences between pairs of registers. The registers with different initial states or different clock signals are not considered equivalent. The assume and disprove method is applied to identify equivalent registers. The assume and disprove method starts with assigning one identifier per equivalent class and assuming all registers within class are equivalent. An identifier is applied to the outputs of all registers within that class. The partial or random simulation is applied to determine whether all the registers in the class are functionally equivalent, which further refines the class. The registers are subjected to SAT proof to validate equivalent classes and based on the results, new equivalent classes are created. If no new equivalent classes are found, then result is determined to be final. If additional equivalent classes are found, the entire process will be repeated until no new equivalent classes are found.

In one example, complex registers that may not be merged only considering that the respective next-state value is equivalent are determined. For example, two registers with a different enable signal or different clock signal cannot be merged. The corresponding registers are grouped into compatible classes such that the found equivalences are applicable. As is described above, the registers are set to part of the same equivalence class, and the classes are iteratively refined. A list of equivalent registers are determined and stored within a memory device.

In one or more examples, ungrouping is performed based on the determined constant registers, constant ports, and the equivalent registers. For example, hierarchies associated with the constant registers are ungrouped. Further, the hierarchies associated with the constant ports are ungrouped, and the hierarchies associated with the equivalent registers are ungrouped. In one example, the processing device determines the hierarchies that include (e.g., are associated with) constant registers based on the list of constant registers as determined above and ungroups the hierarchies. The processing device determines the hierarchies that include (e.g., are associated with) constant ports based on the list of constant ports as determined above and ungroups the hierarchies. The processing device determines the hierarchies that include (e.g., are associated with) equivalent registers based on the list of equivalent registers as determined above and ungroups the hierarchies.

In one or more examples, the hierarchies that are ungrouped at 150 of the method 100 and based on the equivalency metric are hierarchies that are not ungrouped at 120, 130, or 140 of the method 100. For example, first hierarchies of a circuit design are ungrouped based on a size parameter at 120 of the method 100, second hierarchies of the circuit design are ungrouped based on the XOR parameter at 130 of the method 100, third hierarchies of the circuit design are ungrouped based on the connectivity parameter at 140 of the method 100, and fourth hierarchies of the circuit design are ungrouped based on the equivalency metric at 150 of the method 100. In one or more examples, the equivalence metric is used to make decisions based on the equivalence-based ungrouping. The other ungrouping processes as are described above are not based on the equivalence-based ungrouping. The equivalence data is collected by exploiting methods based on SAT for both combinational and sequential equivalences. In one or more examples, combinational equivalences are extracted using SAT-sweeping. Sequential equivalences are extracted using assume and disprove methods leveraging SAT-solving for the proofs.

At 160, an updated circuit design is generated. In one example, a processing device (e.g., the processing device 1202 of FIG. 12) executes instructions (e.g., the instructions 1226 of FIG. 12) stored within a memory device (e.g., the main memory 1204 of FIG. 12 and/or the machine-readable medium 1224 of FIG. 12) to generate an updated circuit design. In one example, the updated circuit design is generated to include the ungrouped hierarchies as is described above with regard to one or more of 120, 130, 140, and 150 of the method 100. In one or more examples, 120, 130, 140, and 150 of the method 100 may be performed in a different order than that disclosed in FIG. 1. In one or more examples, at least one of 120, 130, 140, and 150 of the method 100 are performed during a period that at least partially overlaps with a period when another one or more of 120, 130, 140, and 150 of the method 100 are performed.

In one or more examples, 120 and 130 of the method 100 are performed and if a hierarchy is determined to satisfy a size threshold (e.g., smaller than or equal to the size threshold), 140 and/or 150 of the method 100 may not be performed. 140 and/or 150 of the method 100 may not be performed (e.g., skipped) as a hierarchy that is determined to satisfy the size threshold will be ungrouped regardless of the outcome of 140 and 150 of the method 100. 120 and 130 of the method 100 may be less runtime expensive (e.g., use less processing resources and/or processing time) as compared to 140 and/or 150 of the method 100.

In one or more examples, the updated circuit design includes a more flattened circuit design that includes a reduced number of hierarchies as the circuit design received at 110 of the method 100. The updated circuit design is a more flattened circuit design as compared to the circuit design received at 110 of the method 100. The updated circuit design is stored in a memory device.

In one or more examples, the updated circuit design is used to verify the functionality of the circuit design. The verified circuit design is used in the manufacturing of a corresponding IC device. In one example, the verified circuit design is stored in a memory and used in the manufacturing of a corresponding IC device. In one example, the updated circuit design is as an input to an EDA process. For example, the circuit design is input to an emulation environment to perform EDA processes and verify the circuit design.

In one or more examples, a method includes receiving a circuit design. The method further includes determining, by a processor, an equivalency metric across a first hierarchy and a second hierarchy from hierarchies of the circuit design. The equivalency metric is based on one or more of a combinational element equivalency and a sequential element equivalency across the first hierarchy and the second hierarchy. Further, the method includes generating an updated circuit design by ungrouping the first hierarchy of the hierarchies into the second hierarchy of the hierarchies based on the equivalency metric. In one or more examples, determining the equivalency metric comprises determining a cross-boundary equivalency for two hierarchies of the hierarchies of the circuit design, and ungrouping the two hierarchies based on determining the cross-boundary equivalency. In one or more examples, determining the equivalency metric from the hierarchies of the circuit design includes determining the combinational element equivalency by determining a global network for the hierarchies, and determining a first node and a second node from the global network that are equivalent. In one or more examples, determining the equivalency metric comprises determining the sequential element equivalency within the circuit design comprising determining at least one or more of one or more registers associated with a constant value, one or more equal registers associated with a constant port, and a pair of equivalent registers. In one or more examples, determining the one or more registers associated with a constant value comprises setting an input signal of the one or more registers to a constant value. In one or more examples, ungrouping a third hierarchy of the circuit design based on a size parameter of the third hierarchy. The size parameter corresponds to a number of logic elements of the third hierarchy. In one or more examples, the method further includes ungrouping a fourth hierarchy of the circuit design based on an XOR-parameter of the fourth hierarchy. The XOR-parameter corresponds to a number of XOR equivalent gates within the fourth hierarchy. In one or more examples, the method further includes ungrouping a fifth hierarchy of the circuit design based on a connectivity parameter of the fifth hierarchy. The connectivity parameter corresponds to connections between arithmetic operators of the fifth hierarchy.

In one or more examples, a system includes a memory storing instructions and a processor coupled with the memory. The processor executes the instructions. The instructions when executed cause the processor to receive a circuit design, and determine an equivalency metric across a first hierarchy and a second hierarchy from hierarchies of the circuit design. The equivalency metric is based on one or more of a combinational element equivalency and a sequential element equivalency across the first hierarchy and the second hierarchy. Further, the instructions, when executed, cause the processor to generate an updated circuit design by ungrouping the first hierarchy of the hierarchies into the second hierarchy of the hierarchies based on the equivalency metric. In one or more examples, determining the equivalency metric includes determining a cross-boundary equivalency for two hierarchies of the hierarchies of the circuit design, and ungrouping the two hierarchies based on determining the cross-boundary equivalency. In one or more examples, determining the equivalency metric from the hierarchies of the circuit design includes determining the combinational element equivalency by determining a global network for the hierarchies, and determining a first node and a second node from the global network that are equivalent. In one or more examples, determining the equivalency metric comprises determining the sequential element equivalency within the circuit design comprising determining at least one or more of one or more registers associated with a constant value, one or more equal registers associated with a constant port, and a pair of equivalent registers. In one or more examples, determining the one or more registers associated with a constant value comprises setting an input signal of the one or more registers to a constant value. In one or more examples, the processor is further caused to ungroup a third hierarchy of the circuit design based on a size parameter of the third hierarchy, wherein the size parameter corresponds to a number of logic elements of the third hierarchy. In one or more examples, the processor is further caused to ungroup a fourth hierarchy of the circuit design based on an XOR parameter of the fourth hierarchy. The XOR parameter corresponds to a number of XOR equivalent gates within the fourth hierarchy. In one or more examples, the processor is further caused to ungroup a fifth hierarchy of the circuit design based on a connectivity parameter of the fifth hierarchy. The connectivity parameter corresponds to connections between arithmetic operators of the fifth hierarchy.

In one or more examples, a non-transitory computer readable medium includes stored instructions, which when executed by a processor, cause the processor to receive a circuit design and ungroup a first hierarchy to combine into a second hierarchy of the circuit design based on determining whether to use one or more of an XOR parameter, an equivalency metric, and a connectivity parameter. The XOR parameter corresponds to a number of XOR equivalent gates within the first hierarchy and the second hierarchy. The equivalency metric is based on one or more of a combinational element equivalency and a sequential element equivalency across the first hierarchy and the second hierarchy. The connectivity parameter is based on connections between arithmetic operators across the first hierarchy and the second hierarchy. The processor is further caused to generate an updated circuit design based on the ungrouped first hierarchy that is combined into the second hierarchy. In one or more examples, determining the sequential element equivalency comprises determining, for the first hierarchy, at least one or more of one or more registers associated with a constant value, one or more equal registers associated with a constant port, and a pair of equivalent registers. In one or more examples, determining the one or more registers associated with a constant value comprises setting an input signal of the one or more registers to a constant value. In one or more examples, the combinational element equivalency is determined by determining a global network for the hierarchies, and determining a first node and a second node from the global network that are equivalent.

FIG. 11 illustrates an example set of processes 1100 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1110 with information supplied by a designer, information which is transformed to create an article of manufacture that uses a set of EDA processes 1112. When the design is finalized, the design is taped-out 1134, which is when artwork (e.g., geometric patterns) for the integrated circuit is sent to a fabrication facility to manufacture the mask set, which is then used to manufacture the integrated circuit. After tape-out, a semiconductor die is fabricated 1136 and packaging and assembly processes 1138 are performed to produce the finished integrated circuit 1140.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 11. The processes described may be enabled by EDA products (or EDA systems).

During system design 1114, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1116, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1118, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1120, the netlist is checked for compliance with timing constraints and for correspondence with the HDL code. During design planning 1122, an overall floor plan for the integrated circuit is constructed and analyzed for timing and top-level routing.

During layout or physical implementation 1124, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1126, the circuit function is verified at the layout level, which permits refinement of the layout design. During physical verification 1128, the layout design is checked to ensure that manufacturing constraints are correct, such as DRC constraints, electrical constraints, lithographic constraints, and that circuitry function matches the HDL design specification. During resolution enhancement 1130, the geometry of the layout is transformed to improve how the circuit design is manufactured.

During tape-out, data is created to be used (after lithographic enhancements are applied if appropriate) for production of lithography masks. During mask data preparation 1132, the ‘tape-out’ data is used to produce lithography masks that are used to produce finished integrated circuits.

A storage subsystem of a computer system (such as computer system 1200 of FIG. 12) may be used to store the programs and data structures that are used by some or all of the EDA products described herein, and products used for development of cells for the library and for physical and logical design that use the library.

FIG. 12 illustrates an example machine of a computer system 1200 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1200 includes a processing device 1202, a main memory 1204 (e.g., read-only memory (ROM), flash memory, dynamic random access memory (DRAM) such as synchronous DRAM (SDRAM), a static memory 1206 (e.g., flash memory, static random access memory (SRAM), etc.), and a data storage device 1218, which communicate with each other via a bus 1230.

Processing device 1202 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1202 may also be one or more special-purpose processing devices such as an application specific integrated circuit (ASIC), a field programmable gate array (FPGA), a digital signal processor (DSP), network processor, or the like. The processing device 1202 may be configured to execute instructions 1226 for performing the operations and steps described herein.

The computer system 1200 may further include a network interface device 1208 to communicate over the network 1220. The computer system 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), a graphics processing unit 1222, a signal generation device 1216 (e.g., a speaker), graphics processing unit 1222, video processing unit 1228, and audio processing unit 1232.

The data storage device 1218 may include a machine-readable storage medium 1224 (also known as a non-transitory computer-readable medium) on which is stored one or more sets of instructions 1226 or software embodying any one or more of the methodologies or functions described herein. The instructions 1226 may also reside, completely or at least partially, within the main memory 1204 and/or within the processing device 1202 during execution thereof by the computer system 1200, the main memory 1204 and the processing device 1202 also constituting machine-readable storage media.

In some implementations, the instructions 1226 include instructions to implement functionality corresponding to the present disclosure. While the machine-readable storage medium 1224 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1202 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving a circuit design;
determining, by a processor, an equivalency metric across a first hierarchy and a second hierarchy from hierarchies of the circuit design, wherein the equivalency metric is based on one or more of a combinational element equivalency and a sequential element equivalency across the first hierarchy and the second hierarchy; and
generating an updated circuit design by ungrouping the first hierarchy of the hierarchies into the second hierarchy of the hierarchies based on the equivalency metric.

2. The method of claim 1, wherein determining the equivalency metric comprises:
determining a cross-boundary equivalency for two hierarchies of the hierarchies of the circuit design; and
ungrouping the two hierarchies based on determining the cross-boundary equivalency.

3. The method of claim 1, wherein determining the equivalency metric from the hierarchies of the circuit design includes determining the combinational element equivalency by:
determining a global network for the hierarchies; and
determining a first node and a second node from the global network that are equivalent.

4. The method of claim 1, wherein determining the equivalency metric comprises determining the sequential element equivalency within the circuit design comprising determining at least one or more of one or more registers associated with a constant value, one or more equal registers associated with a constant port, and a pair of equivalent registers.

5. The method of claim 4, wherein determining the one or more registers associated with a constant value comprises setting an input signal of the one or more registers to a constant value.

6. The method of claim 1, further comprising ungrouping a third hierarchy of the circuit design based on a size parameter of the third hierarchy, wherein the size parameter corresponds to a number of logic elements of the third hierarchy.

7. The method of claim 1, further comprising ungrouping a fourth hierarchy of the circuit design based on an XOR-parameter of the fourth hierarchy, wherein the XOR-parameter corresponds to a number of XOR equivalent gates within the fourth hierarchy.

8. The method of claim 1, further comprising ungrouping a fifth hierarchy of the circuit design based on a connectivity parameter of the fifth hierarchy, wherein the connectivity parameter corresponds to connections between arithmetic operators of the fifth hierarchy.

9. A system comprising:
a memory storing instructions; and
a processor, coupled with the memory and to execute the instructions, the instructions when executed cause the processor to:
receive a circuit design;
determine an equivalency metric across a first hierarchy and a second hierarchy from hierarchies of the circuit design, wherein the equivalency metric is based on one or more of a combinational element equivalency and a sequential element equivalency across the first hierarchy and the second hierarch; and
Generate an updated circuit design by ungrouping the first hierarchy of the hierarchies into the second hierarchy of the hierarchies based on the equivalency metric.

10. The system of claim 9, wherein determining the equivalency metric comprises:
determining a cross-boundary equivalency for two hierarchies of the hierarchies of the circuit design; and
ungrouping the two hierarchies based on determining the cross-boundary equivalency.

11. The system of claim 9, wherein determining the equivalency metric from the hierarchies of the circuit design includes determining the combinational element equivalency by:
determining a global network for the hierarchies; and
determining a first node and a second node from the global network that are equivalent.

12. The system of claim 9, wherein determining the equivalency metric comprises determining the sequential element equivalency within the circuit design comprising determining at least one or more of one or more registers associated with a constant value, one or more equal registers associated with a constant port, and a pair of equivalent registers.

13. The system of claim 12, wherein determining the one or more registers associated with a constant value comprises setting an input signal of the one or more registers to a constant value.

14. The system of claim 9, wherein the processor is further caused to ungroup a third hierarchy of the circuit design based on a size parameter of the third hierarchy, wherein the size parameter corresponds to a number of logic elements of the third hierarchy.

15. The system of claim 9, wherein the processor is further caused to ungroup a fourth hierarchy of the circuit design based on an XOR parameter of the fourth hierarchy, wherein the XOR parameter corresponds to a number of XOR equivalent gates within the fourth hierarchy.

16. The system of claim 9, wherein the processor is further caused to ungroup a fifth hierarchy of the circuit design based on a connectivity parameter of the fifth hierarchy, wherein the connectivity parameter corresponds to connections between arithmetic operators of the fifth hierarchy.

17. A non-transitory computer readable medium comprising stored instructions, which when executed by a processor, cause the processor to:
receive a circuit design;
ungroup a first hierarchy to combine into a second hierarchy of the circuit design based on determining whether to use one or more of an XOR parameter, an equivalency metric, and a connectivity parameter,
wherein the XOR parameter corresponds to a number of XOR equivalent gates within the first hierarchy and the second hierarchy,
wherein the equivalency metric is based on one or more of a combinational element equivalency and a sequential element equivalency across the first hierarchy and the second hierarchy,
wherein the connectivity parameter is based on connections between arithmetic operators across the first hierarchy and the second hierarchy; and
generate an updated circuit design based on the ungrouped first hierarchy that is combined into the second hierarchy.

18. The non-transitory computer readable medium of claim 17, wherein determining the sequential element equivalency comprises determining, for the first hierarchy, at least one or more of one or more registers associated with a constant value, one or more equal registers associated with a constant port, and a pair of equivalent registers.

19. The non-transitory computer readable medium of claim 18, wherein determining the one or more registers associated with a constant value comprises setting an input signal of the one or more registers to a constant value.

20. The non-transitory computer readable medium of claim 17, wherein the combinational element equivalency is determined by:
determining a global network for the hierarchies; and
determining a first node and a second node from the global network that are equivalent.
